(19) United States
(12) Patent Application Publication
(10) Pub. No.: US 2025/0393446 A1
(43) Pub. Date: Dec. 25, 2025

(54) PIXELATED ACTIVE DISPLAY PANEL WITH POLARIZED LIGHT EMISSION

(71) Applicant: Meta Platforms Technologies, LLC, Menlo Park, CA (US)

(72) Inventors: Zhimin Shi, Bellevue, WA (US); Donghee Nam, San Jose, CA (US); Zhaoning Yu, Redmond, WA (US); Yun Wang, Bellevue, WA (US)

(21) Appl. No.: 18/751,882

(22) Filed: Jun. 24, 2024

(51) Int. Cl. H10K 59/80

(52) U.S. Cl. CPC H10K 59/878; H10K 59/8051; H10K 59/8052; H10K 59/8791

(57) ABSTRACT

A display panel includes a meta-reflector and an organic light-emitting diode, the organic light-emitting diode having an anode disposed over and spaced away from the meta-reflector, an emissive layer overlying the anode, and a cathode overlying the emissive layer. The organic light-emitting diode is configured to emit polarized light.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a cross-sectional view of an example emitter structure for an active display panel according to some embodiments.

FIG. 2 is a cross-sectional view of a further example emitter structure according to some embodiments.

FIG. 3 is a still further cross-sectional view of an emitter structure for an active display panel according to certain embodiments.

FIG. 4 depicts the resonance conditions for a meta reflector-containing emitter structure according to various embodiments.

FIG. 5 shows example meta-reflector structures in accordance with some embodiments.

FIG. 6 shows a simulation of phase shift for two orthogonal linear polarizations incident upon an example emitter structure according to some embodiments.

FIG. 7 illustrates example bottom reflector architectures according to various embodiments.

FIG. 8 depicts various nano-resonator architectures according to some embodiments.

FIG. 9 illustrates example bottom meta-reflector architectures according to some embodiments.

FIG. 10 shows cross-sectional views of example bottom reflector structures for an active display pixel according to various embodiments.

FIG. 11 depicts common cathode and top reflector architectures according to some embodiments.

FIG. 12 depicts isolated cathode and top reflector architectures according to some embodiments.

FIG. 13 is a schematic illustration depicting a spatially-varying polarization state across an example display panel according to certain embodiments.

FIG. 14 is an illustration of exemplary augmented-reality glasses that may be used in connection with embodiments of this disclosure.

FIG. 15 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Organic light emitting diode (OLED)-based micro-display panels are a promising high pixel density display technology for future VR and AR systems. Comparative micro-display devices and panels emit only unpolarized light, however, which leads to at least a 50% loss of available intensity in display systems when co-integrated with polarization sensitive components such as pancake lenses.

Disclosed is a micro-OLED display panel configuration with pixelated color emission that can provide polarized output light. In exemplary embodiments, each emitter includes one or more meta-reflectors having a reflection coefficient (amplitude and phase) configured to be polarization and/or angle dependent. A combination of the meta-reflectors with selected electroluminescent material(s), capping material(s), and planarization material(s), may define colored and emissive pixels configured to provide enhanced light extraction efficiency, polarization state, and emission geometry at a desired wavelength.

According to particular embodiments, a meta-reflector may be configured to provide polarization-dependent phase shift in its reflection coefficient by controlling the lateral (transverse) subwavelength geometry to be both wavelength and polarization dependent. In this way, reflectors for different wavelengths (RGB) can be fabricated using a common process by changing the transverse geometry. Moreover, different groups of pixels can be designed to produce output light having different polarization states, which may enable polarization multiplexing, for example, and pixels located within different areas of the display panel can be arranged to output light of different polarization states (e.g., different ellipticity) to facilitate an angular dependence of other polarization optics within an associated VR or AR system. Also, the reflection properties of each meta-reflector pixel may be designed to tailor the angular profile of light emission.

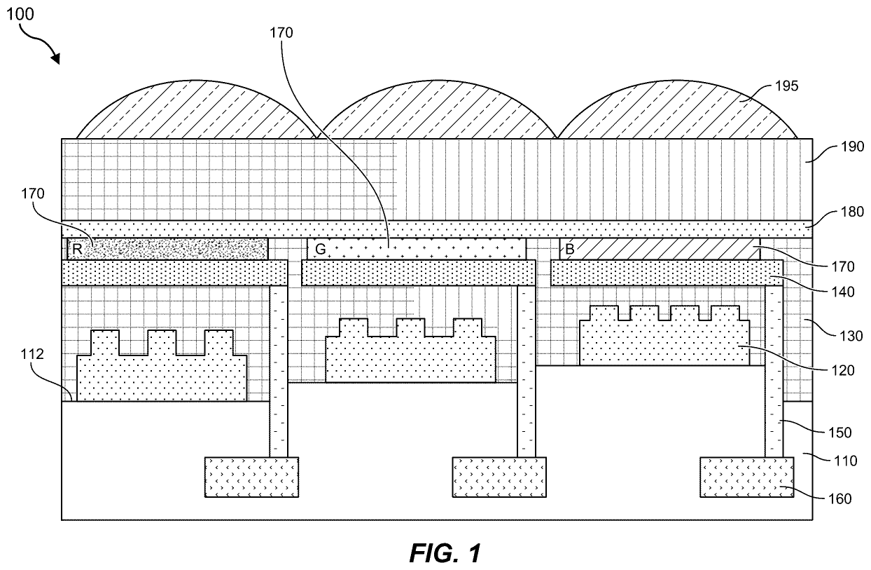

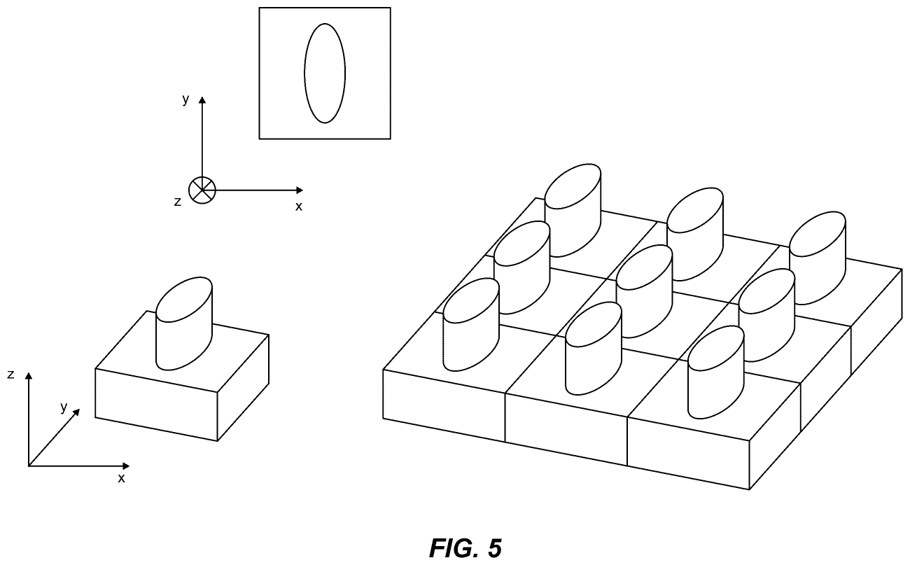

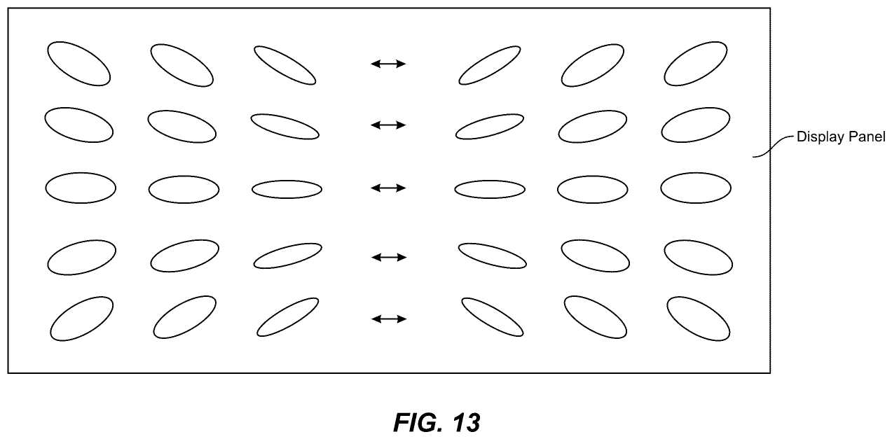

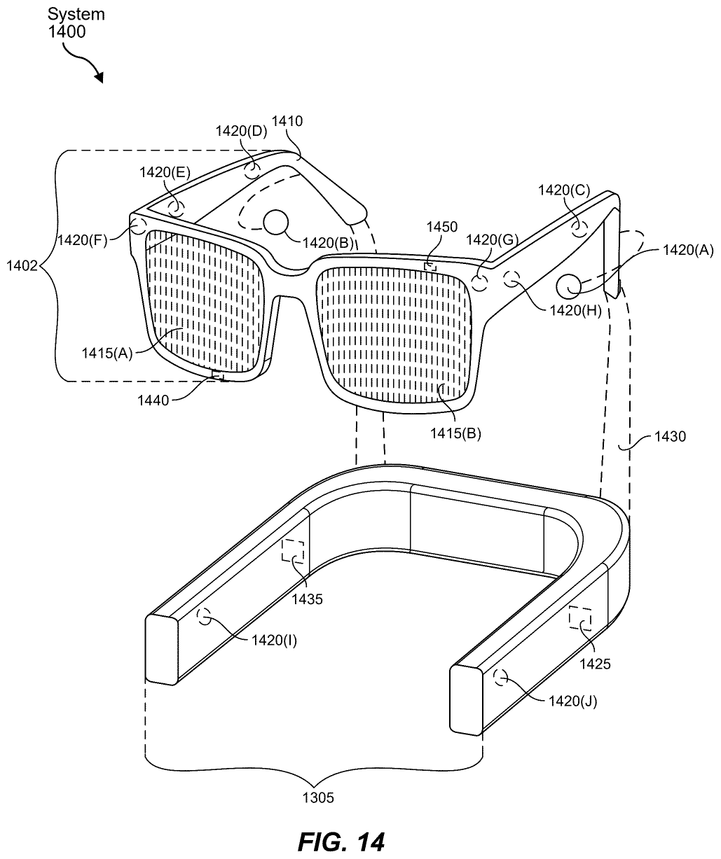

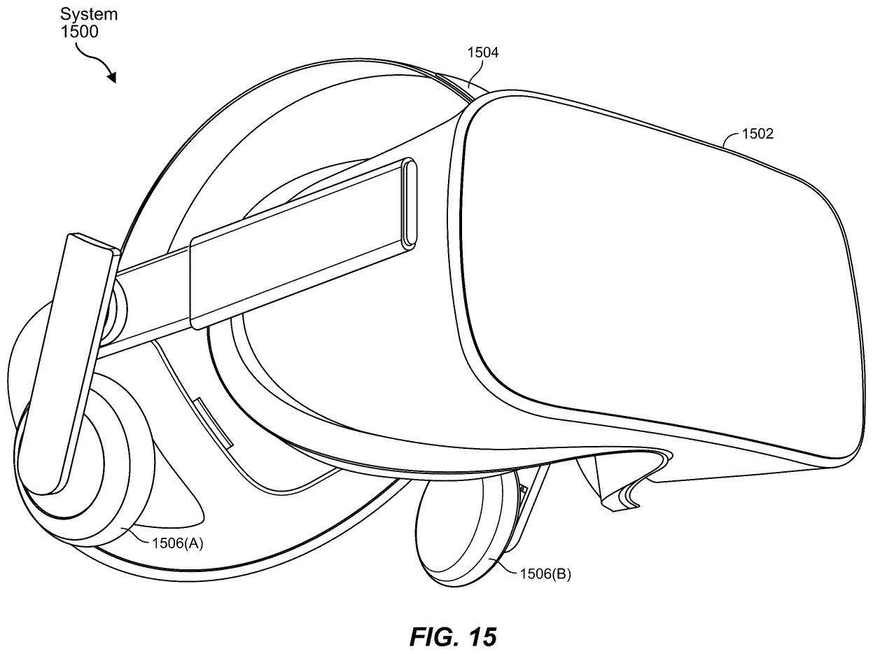

The following will provide, with reference to FIGS. 1-15, detailed descriptions of devices and related methods associated with a pixelated active display having polarized light emission. The discussion associated with FIGS. 1-4 includes a description of example display architectures and their principle of operation. The discussion associated with FIGS. 5-12 includes a description of various resonator and reflector structures. The discussion associated with FIG. 13 includes a description of a pixelated active display having polarized light emission. The discussion associated with FIGS. 14 and 15 relates to exemplary virtual reality and augmented reality devices that may include one or more pixelated display panels as disclosed herein.

Referring to FIG. 1, shown is a cross-sectional view of an example display panel architecture. Display 100 includes a substrate 110 having a multi-tiered top surface 112 with a bottom meta-reflector element 120 formed over each tier. A planarization layer 130 is disposed over the substrate 110 and over each bottom meta-reflector element 120. An optically transparent anode 140 overlies and is spaced away from each respective bottom meta-reflector element 120 and is electrically connected through metallization vias 150 to electronic circuitry 160 for the display panel.

A patterned electroluminescent layer 170 overlies each respective pixelated anode 140 and a top reflector/common cathode 180 is formed over the array of electroluminescent layers 170. The electroluminescent layers 170 may include carrier transport and blocking layers (not separately shown). A capping layer 190 may be formed over the foregoing structure and display optics 195, such as a micro-lens array or other beam-shaping elements, may be formed over the capping layer 190.

In the embodiment of FIG. 1, a spacing between the pixelated anode 140 and each respective bottom meta-reflector element 120 may be tuned to adjust the light extraction efficiency of each colored pixel. According to various embodiments, the bottom meta-reflector elements 120 may include a single layer or a multilayer structure, including alternating dielectric and metal layer configurations. In certain embodiments, the individual bottom meta-reflector elements 120 may be electrically connected to respective portions of the pixelated anode 140 through the metallization vias 150. An optional waveplate (not shown) may be configured to further adjust polarization states and may be located between the bottom meta-reflector element 120 and the top reflector/common cathode 180.

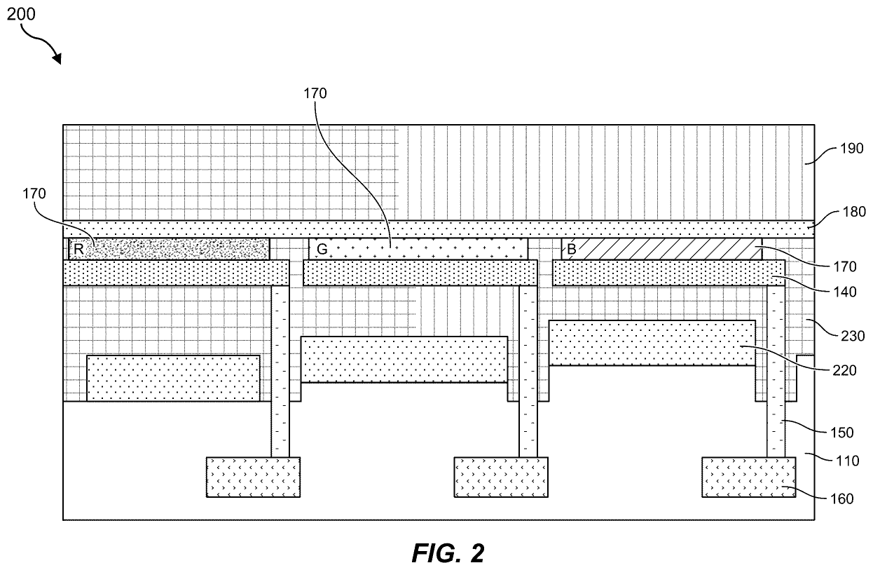

Referring to FIG. 2, shown is a cross-sectional view of a further example display panel architecture. Display 200 is analogous to display 100. Display 200 may include unstructured reflector elements 220 and a planarization layer 230 overlying the reflector elements 220 that includes an optically anisotropic (i.e., birefringent) spacer material, which may be configured to improve the light extraction efficiency of each colored pixel for a desired polarization. The optically anisotropic planarization layer 230 may be configured to enhance emission of a desired polarization state and suppress emission of an undesired polarization state.

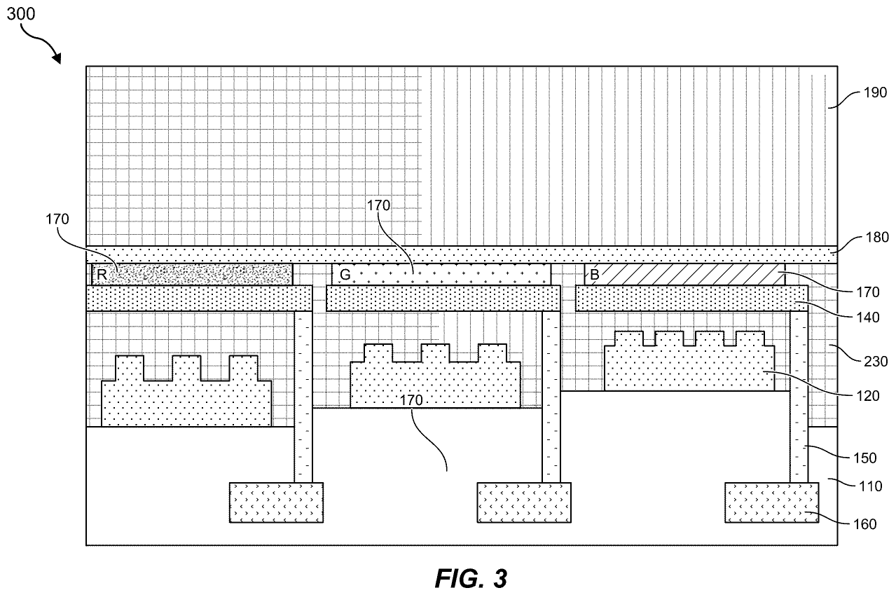

Turning to FIG. 3, shown is a cross-sectional view of a still further example display panel architecture. Display 300 is analogous to display 100. Display 300 includes bottom meta-reflector elements 120 and an anisotropic planarization layer 230. To enhance emission, an optical cavity is formed between top and bottom reflector elements for a selected wavelength and polarization.

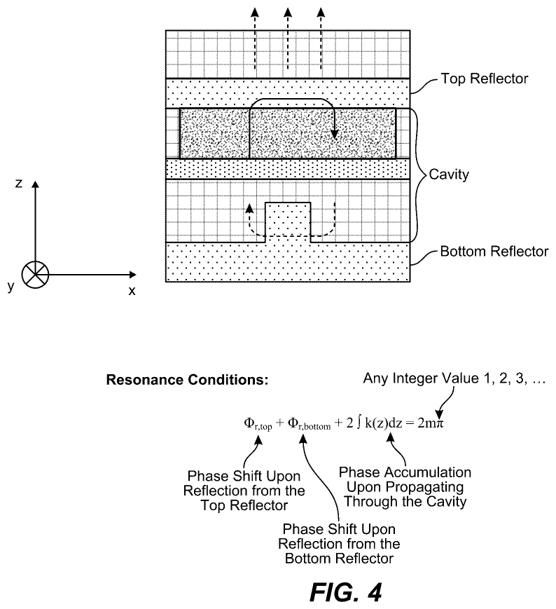

A principle of operation illustrating a resonance enhancement phenomenon for a reflector cavity located between top and bottom reflector elements is illustrated schematically in FIG. 4. Without wishing to be bound by theory, provided is a resonance condition for a desired polarization according to Ø_{r,top}+Ø_{r,bottom}+2∫k(z)dz ˜2mπ, and an anti-resonance condition for an undesired polarization according to Ø_{r,top}+Ø_{r,bottom}+2∫k(z)dz ˜(2m+1)π.

As will be appreciated, the phase shift upon reflection from a meta-reflector may be highly polarization sensitive such that the output efficiency of dipole emission within the electroluminescent (EL) layer of a desired polarization state is at least 50% greater than that for an undesired polarization state. Accordingly, in certain embodiments, a meta-reflector may be configured to provide a resonance condition that is valid for only a particular polarization state (e.g., linear, circular, or elliptical).

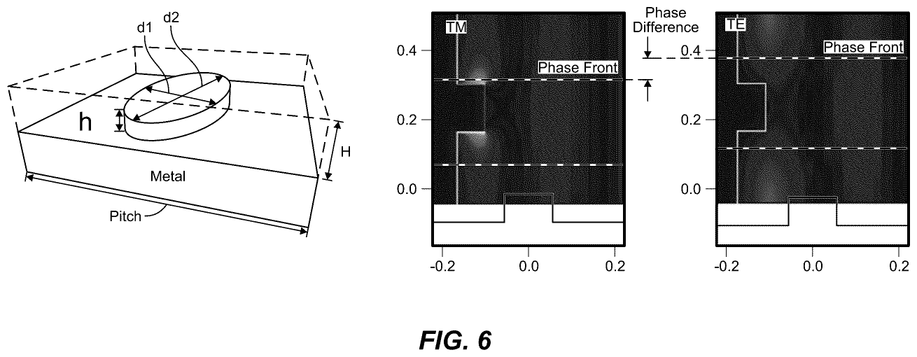

Referring to FIG. 5, a polarization sensitive meta-reflector may include a 1D or 2D array of features, such as a plurality of anisotropic metallic nanoscale pillars located over a continuous layer of a metal thin film. By interrupting the x-y symmetry of the meta-reflectors, a reflection phase shift for x- and y-linear polarization components can be different, for example. Such a phase difference is illustrated in the modeled data shown in FIG. 6, where the two orthogonal polarization states are 180° out of phase.

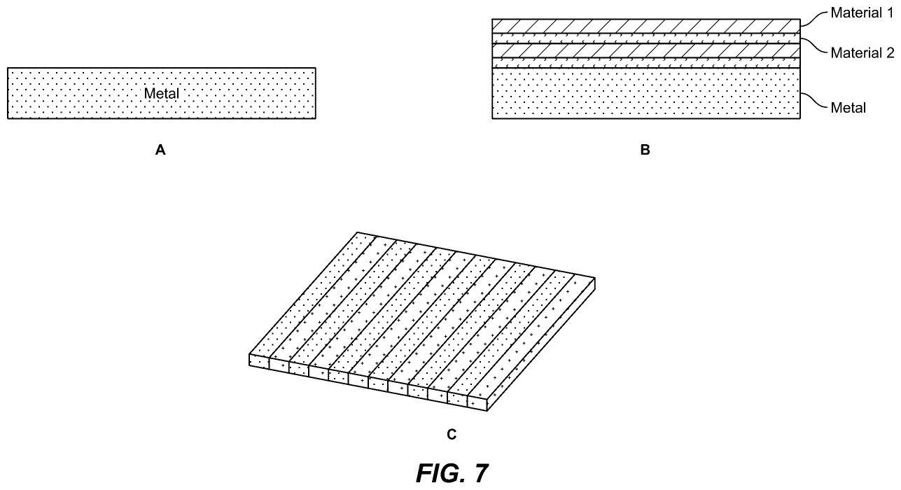

Referring to FIG. 7, illustrated are various bottom reflector element configurations, including a metal thin film (FIG. 7A) and a multilayer stack of alternating material/layer thickness (FIG. 7B). In a multilayer arrangement, each layer may be independently selected from a dielectric material, a metallic material, a semiconducting material, or a random or structured composite of two or more such materials. Further example bottom reflector element configurations may include a 1D or 2D grating layer having a sub-wavelength pitch (FIG. 7C).

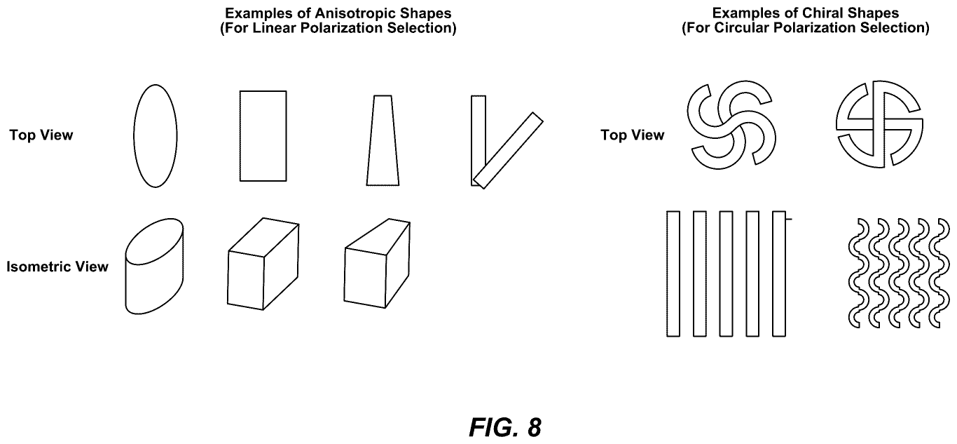

Example nano-resonator architectures are illustrated in FIG. 8. Plural resonator elements may be isolated or interconnected and may include a three-dimensional, quasi three-dimensional, two-dimensional, or quasi two-dimensional nanostructure configured to exhibit optical resonance. The nano-resonators may be formed using a metal (e.g., Al, Ag, MgAg, LiF/Al, etc.), dielectric, semiconductor, or combinations thereof.

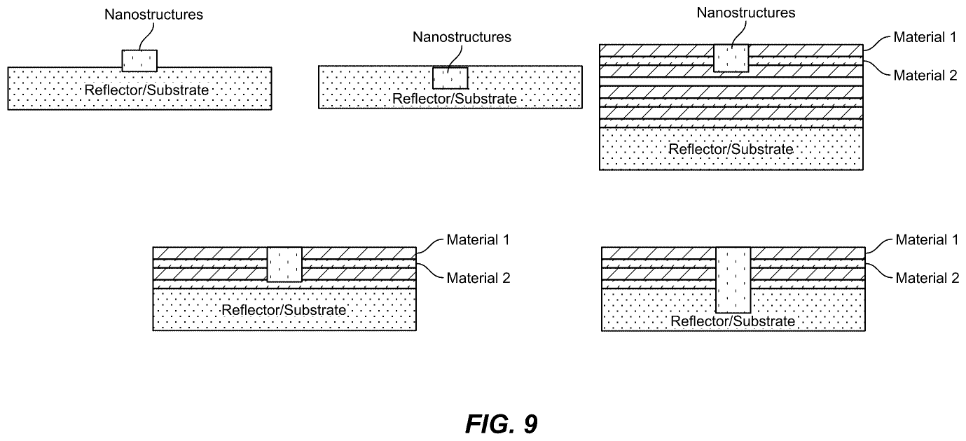

The co-integration of reflector and resonator structures is shown in FIG. 9. In certain examples, a polarization sensitive meta-reflector may include an array of anisotropic or chiral-shaped nanostructures that are formed over or embedded within a transversely uniform layer of a metal or dielectric or semiconductor or composite thin film.

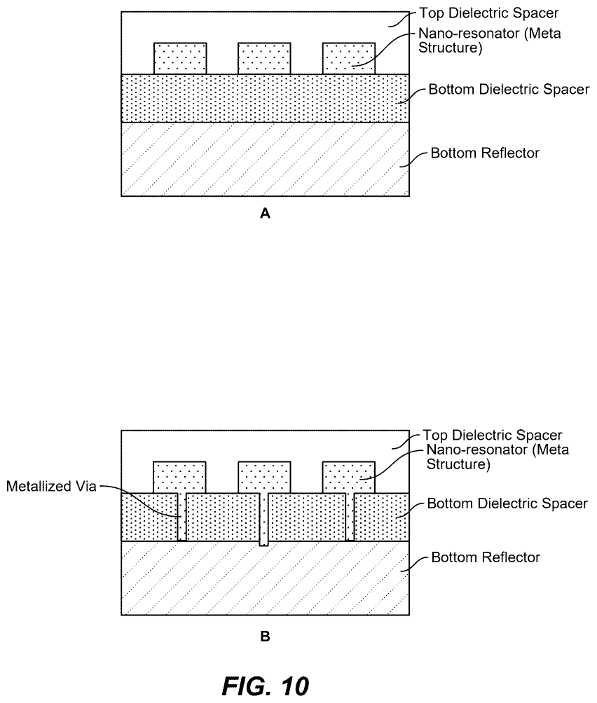

Referring to FIG. 10, and initially FIG. 10A, a nano-resonator structure may be separated from a bottom reflector by a bottom dielectric spacer layer. As shown in FIG. 10B, according to further embodiments, a nano-resonator structure may be electrically connected to a bottom reflector using a conductive via that extends through a bottom dielectric spacer layer.

In the illustrated examples, a top dielectric spacer layer may overlie the nano-resonator structures such that the nano-resonators are enveloped by a dielectric material. The bottom and top dielectric spacer layer may include one or more dielectric materials, such as a dielectric nano-composite material or a layered structure having plural dielectric material layers.

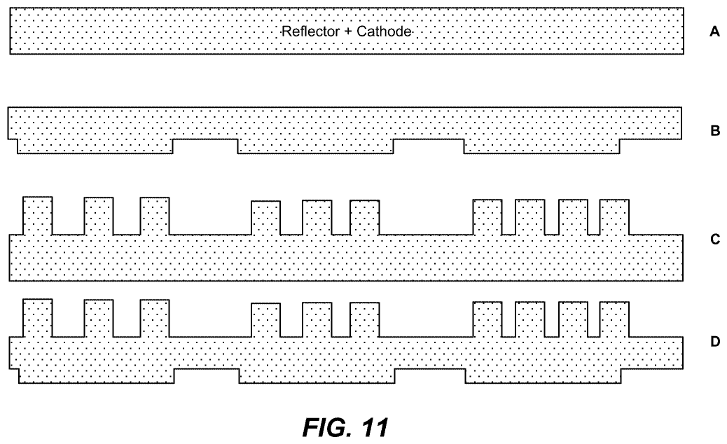

Referring to FIG. 11, shown are example top reflector element geometries. As disclosed herein, a top reflector may be configured to operate as both a partial reflector and a common cathode. Such hybrid elements may include (A) a uniform metallic thin film, (B) a metallic thin film having bottom-side pixelated contacts to improve current confinement, (C) a uniform metallic thin film at the bottom co-integrated with top-side nanostructures, and (D) a metallic thin film having pixelated contacts at the bottom co-integrated with top-side nanostructures. A top reflector can also be pixelated and locally controlled.

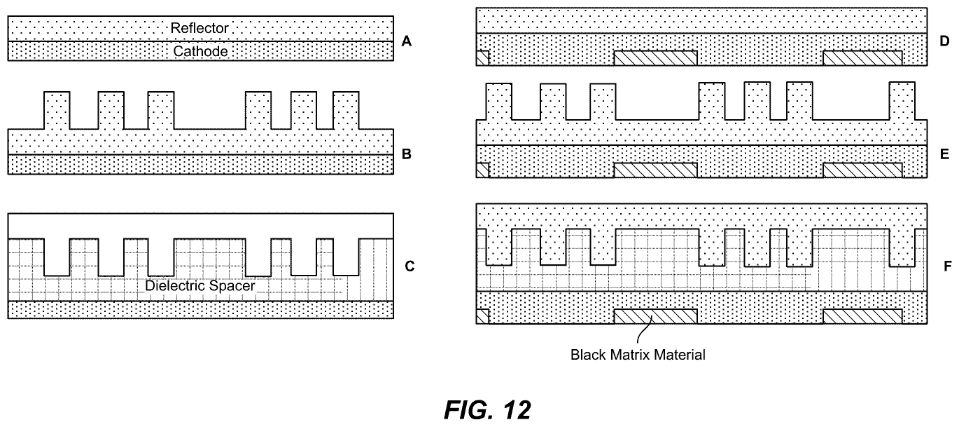

According to still further embodiments, the top reflector may be configured independently from the top cathode. Representative structures are shown in FIGS. 12A-12F and include a cathode with an overlying patterned or un-patterned reflector. The top reflector and the cathode may or may not be electrically connected.

In certain embodiments, the polarization of emitted light within a display panel may be spatially variable and accordingly configured to operate angularly-dependent polarization optics. Additionally, a spatial polarization variation may be color dependent, where each of a plurality of colored sub-pixels may emit a different polarization state to address a chromatic dependence of the polarization optics. An example of a display panel having a spatially-varying polarization state is shown schematically in FIG. 13.

### Example Embodiments

Example 1: A display panel includes a meta-reflector and an organic light-emitting diode overlying the meta-reflector, the organic light-emitting diode having: an anode disposed adjacent and spaced away from the meta-reflector, an emissive layer overlying the anode, and a cathode overlying the emissive layer.

Example 2: The display panel of Example 1, where the meta-reflector includes a nanostructured surface facing the anode.

Example 3: The display panel of any of Examples 1 and 2, where the organic light-emitting diode is configured to emit polarized light.

Example 4: The display panel of any of Examples 1-3, where the organic light-emitting diode is configured to enhance light emission having a first polarization state and suppress light emission having a second polarization state orthogonal to the first polarization state.

Example 5: The display panel of any of Examples 1-4, where the meta-reflector is electrically connected to the anode.

Example 6: The display panel of any of Examples 1-5, where the cathode includes a reflector.

Example 7: The display panel of any of Examples 1-5, further including a reflector overlying the cathode.

Example 8: The display panel of any of Examples 1-3, further including a dielectric layer between the meta-reflector and the anode.

Example 9: The display panel of Example 8, where the dielectric layer is optically anisotropic.

Example 10: A pixelated display panel includes a plurality of organic light-emitting diodes, each organic light-emitting diode having: an anode, an emissive layer overlying the anode, and a common cathode overlying the emissive layer, a plurality of bottom reflectors, each bottom reflector located proximate to a respective anode, and a spacer layer located between each of the plurality of bottom reflectors and each of the respective anodes.

Example 11: The pixelated display panel of Example 10, where each organic light-emitting diode is configured to emit polarized light.

Example 12: The pixelated display panel of any of Examples 10 and 11, where each of the plurality of bottom reflectors includes an independently-configured meta surface.

Example 13: The pixelated display panel of any of Examples 10-12, where the plurality of bottom reflectors include a multilayer structure.

Example 14: The pixelated display panel of any of Examples 10-13, where a first bottom reflector includes a first meta surface facing a corresponding first anode, and a second bottom reflector includes a second meta surface facing a corresponding second anode.

Example 15: The pixelated display panel of any of Examples 10-14, where the spacer layer has a first thickness between a first bottom reflector and a first anode corresponding to the first bottom reflector, and a second thickness between a second bottom reflector and a second anode corresponding to the second bottom reflector.

Example 16: The pixelated display panel of any of Examples 10-15, where the spacer layer includes an optically anisotropic dielectric material.

Example 17: The pixelated display panel of any of Examples 10-16, further including a top reflector overlying the common cathode.

Example 18: A display panel includes an organic light-emitting diode disposed between a top reflector and a bottom reflector, where the organic light-emitting diode is configured to emit polarized light.

Example 19: The display panel of Example 18, where the bottom reflector includes a nanostructured surface facing the organic light-emitting diode.

Example 20: The display panel of Example 19, where the nanostructured surface includes a plurality of anisotropic elements.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (e.g., augmented-reality system 1400 in FIG. 14) or that visually immerses a user in an artificial reality (e.g., virtual-reality system 1500 in FIG. 15). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 14, augmented-reality system 1400 may include an eyewear device 1402 with a frame 1410 configured to hold a left display device 1415(A) and a right display device 1415(B) in front of a user's eyes. Display devices 1415(A) and 1415(B) may act together or independently to present an image or series of images to a user. While augmented-reality system 1400 includes two displays, embodiments of this disclosure may be implemented in augmented-reality systems with a single NED or more than two NEDs.

In some embodiments, augmented-reality system 1400 may include one or more sensors, such as sensor 1440. Sensor 1440 may generate measurement signals in response to motion of augmented-reality system 1400 and may be located on substantially any portion of frame 1410. Sensor 1440 may represent a position sensor, an inertial measurement unit (IMU), a depth camera assembly, a structured light emitter and/or detector, or any combination thereof. In some embodiments, augmented-reality system 1400 may or may not include sensor 1440 or may include more than one sensor. In embodiments in which sensor 1440 includes an IMU, the IMU may generate calibration data based on measurement signals from sensor 1440. Examples of sensor 1440 may include, without limitation, accelerometers, gyroscopes, magnetometers, other suitable types of sensors that detect motion, sensors used for error correction of the IMU, or some combination thereof.

Augmented-reality system 1400 may also include a microphone array with a plurality of acoustic transducers 1420(A)-1420(J), referred to collectively as acoustic transducers 1420. Acoustic transducers 1420 may be transducers that detect air pressure variations induced by sound waves. Each acoustic transducer 1420 may be configured to detect sound and convert the detected sound into an electronic format (e.g., an analog or digital format). The microphone array in FIG. 14 may include, for example, ten acoustic transducers: 1420(A) and 1420(B), which may be designed to be placed inside a corresponding ear of the user, acoustic transducers 1420(C), 1420(D), 1420(E), 1420(F), 1420(G), and 1420(H), which may be positioned at various locations on frame 1410, and/or acoustic transducers 1420(I) and 1420(J), which may be positioned on a corresponding neckband 1405.

In some embodiments, one or more of acoustic transducers 1420(A)-(F) may be used as output transducers (e.g., speakers). For example, acoustic transducers 1420(A) and/or 1420(B) may be earbuds or any other suitable type of headphone or speaker.

The configuration of acoustic transducers 1420 of the microphone array may vary. While augmented-reality system 1400 is shown in FIG. 14 as having ten acoustic transducers 1420, the number of acoustic transducers 1420 may be greater or less than ten. In some embodiments, using higher numbers of acoustic transducers 1420 may increase the amount of audio information collected and/or the sensitivity and accuracy of the audio information. In contrast, using a lower number of acoustic transducers 1420 may decrease the computing power required by an associated controller 1450 to process the collected audio information. In addition, the position of each acoustic transducer 1420 of the microphone array may vary. For example, the position of an acoustic transducer 1420 may include a defined position on the user, a defined coordinate on frame 1410, an orientation associated with each acoustic transducer 1420, or some combination thereof.

Acoustic transducers 1420(A) and 1420(B) may be positioned on different parts of the user's ear, such as behind the pinna, behind the tragus, and/or within the auricle or fossa. Or, there may be additional acoustic transducers 1420 on or surrounding the ear in addition to acoustic transducers 1420 inside the ear canal. Having an acoustic transducer 1420 positioned next to an ear canal of a user may enable the microphone array to collect information on how sounds arrive at the ear canal. By positioning at least two of acoustic transducers 1420 on either side of a user's head (e.g., as binaural microphones), augmented reality device 1400 may simulate binaural hearing and capture a 3D stereo sound field around about a user's head. In some embodiments, acoustic transducers 1420(A) and 1420(B) may be connected to augmented-reality system 1400 via a wired connection 1430, and in other embodiments acoustic transducers 1420(A) and 1420(B) may be connected to augmented-reality system 1400 via a wireless connection (e.g., a Bluetooth connection). In still other embodiments, acoustic transducers 1420(A) and 1420(B) may not be used at all in conjunction with augmented-reality system 1400.

Acoustic transducers 1420 on frame 1410 may be positioned along the length of the temples, across the bridge, above or below display devices 1415(A) and 1415(B), or some combination thereof. Acoustic transducers 1420 may be oriented such that the microphone array is able to detect sounds in a wide range of directions surrounding the user wearing the augmented-reality system 1400. In some embodiments, an optimization process may be performed during manufacturing of augmented-reality system 1400 to determine relative positioning of each acoustic transducer 1420 in the microphone array.

In some examples, augmented-reality system 1400 may include or be connected to an external device (e.g., a paired device), such as neckband 1405. Neckband 1405 generally represents any type or form of paired device. Thus, the following discussion of neckband 1405 may also apply to various other paired devices, such as charging cases, smart watches, smart phones, wrist bands, other wearable devices, hand-held controllers, tablet computers, laptop computers, other external compute devices, etc.

As shown, neckband 1405 may be coupled to eyewear device 1402 via one or more connectors. The connectors may be wired or wireless and may include electrical and/or non-electrical (e.g., structural) components. In some cases, eyewear device 1402 and neckband 1405 may operate independently without any wired or wireless connection between them. While FIG. 14 illustrates the components of eyewear device 1402 and neckband 1405 in example locations on eyewear device 1402 and neckband 1405, the components may be located elsewhere and/or distributed differently on eyewear device 1402 and/or neckband 1405. In some embodiments, the components of eyewear device 1402 and neckband 1405 may be located on one or more additional peripheral devices paired with eyewear device 1402, neckband 1405, or some combination thereof.

Pairing external devices, such as neckband 1405, with augmented-reality eyewear devices may enable the eyewear devices to achieve the form factor of a pair of glasses while still providing sufficient battery and computation power for expanded capabilities. Some or all of the battery power, computational resources, and/or additional features of augmented- reality system 1400 may be provided by a paired device or shared between a paired device and an eyewear device, thus reducing the weight, heat profile, and form factor of the eyewear device overall while still retaining desired functionality. For example, neckband 1405 may allow components that would otherwise be included on an eyewear device to be included in neckband 1405 since users may tolerate a heavier weight load on their shoulders than they would tolerate on their heads. Neckband 1405 may also have a larger surface area over which to diffuse and disperse heat to the ambient environment. Thus, neckband 1405 may allow for greater battery and computation capacity than might otherwise have been possible on a stand-alone eyewear device. Since weight carried in neckband 1405 may be less invasive to a user than weight carried in eyewear device 1402, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1405 may be communicatively coupled with eyewear device 1402 and/or to other devices. These other devices may provide certain functions (e.g., tracking, localizing, depth mapping, processing, storage, etc.) to augmented-reality system 1400. In the embodiment of FIG. 14, neckband 1405 may include two acoustic transducers (e.g., 1420(I) and 1420(J)) that are part of the microphone array (or potentially form their own microphone subarray). Neckband 1405 may also include a controller 1425 and a power source 1435.

Acoustic transducers 1420(I) and 1420(J) of neckband 1405 may be configured to detect sound and convert the detected sound into an electronic format (analog or digital). In the embodiment of FIG. 14, acoustic transducers 1420(I) and 1420(J) may be positioned on neckband 1405, thereby increasing the distance between the neckband acoustic transducers 1420(I) and 1420(J) and other acoustic transducers 1420 positioned on eyewear device 1402. In some cases, increasing the distance between acoustic transducers 1420 of the microphone array may improve the accuracy of beamforming performed via the microphone array. For example, if a sound is detected by acoustic transducers 1420(C) and 1420(D) and the distance between acoustic transducers 1420(C) and 1420(D) is greater than, e.g., the distance between acoustic transducers 1420(D) and 1420(E), the determined source location of the detected sound may be more accurate than if the sound had been detected by acoustic transducers 1420(D) and 1420(E).

Controller 1425 of neckband 1405 may process information generated by the sensors on neckband 1405 and/or augmented-reality system 1400. For example, controller 1425 may process information from the microphone array that describes sounds detected by the microphone array. For each detected sound, controller 1425 may perform a direction-of-arrival

(DOA) estimation to estimate a direction from which the detected sound arrived at the microphone array. As the microphone array detects sounds, controller 1425 may populate an audio data set with the information. In embodiments in which augmented-reality system 1400 includes an inertial measurement unit, controller 1425 may compute all inertial and spatial calculations from the IMU located on eyewear device 1402. A connector may convey information between augmented-reality system 1400 and neckband 1405 and between augmented-reality system 1400 and controller 1425. The information may be in the form of optical data, electrical data, wireless data, or any other transmittable data form. Moving the processing of information generated by augmented-reality system 1400 to neckband 1405 may reduce weight and heat in eyewear device 1402, making it more comfortable to the user.

Power source 1435 in neckband 1405 may provide power to eyewear device 1402 and/or to neckband 1405. Power source 1435 may include, without limitation, lithium ion batteries, lithium-polymer batteries, primary lithium batteries, alkaline batteries, or any other form of power storage. In some cases, power source 1435 may be a wired power source. Including power source 1435 on neckband 1405 instead of on eyewear device 1402 may help better distribute the weight and heat generated by power source 1435.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1500 in FIG. 15, that mostly or completely covers a user's field of view. Virtual-reality system 1500 may include a front rigid body 1502 and a band 1504 shaped to fit around a user's head. Virtual-reality system 1500 may also include output audio transducers 1506(A) and 1506(B). Furthermore, while not shown in FIG. 15, front rigid body 1502 may include one or more electronic elements, including one or more electronic displays, one or more inertial measurement units (IMUs), one or more tracking emitters or detectors, and/or any other suitable device or system for creating an artificial reality experience.

Artificial-reality systems may include a variety of types of visual feedback mechanisms. For example, display devices in augmented-reality system 1400 and/or virtual-reality system 1500 may include one or more liquid crystal displays (LCDs), light emitting diode (LED) displays, organic LED (OLED) displays, digital light project (DLP) micro-displays, liquid crystal on silicon (LCoS) micro-displays, and/or any other suitable type of display screen. Artificial-reality systems may include a single display screen for both eyes or may provide a display screen for each eye, which may allow for additional flexibility for varifocal adjustments or for correcting a user's refractive error. Some artificial-reality systems may also include optical subsystems having one or more lenses (e.g., conventional concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some artificial-reality systems may include one or more projection systems. For example, display devices in augmented-reality system 1400 and/or virtual-reality system 1500 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

Artificial-reality systems may also include various types of computer vision components and subsystems. For example, augmented-reality system 1400 and/or virtual-reality system 1500 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

Artificial-reality systems may also include one or more input and/or output audio transducers. In the examples shown in FIG. 15, output audio transducers 1506(A) and 1506(B) may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

While not shown in FIG. 14, artificial-reality systems may include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

While various features, elements or steps of particular embodiments may be disclosed using the transitional phrase “comprising,” it is to be understood that alternative embodiments, including those that may be described using the transitional phrases “consisting of” or “consisting essentially of,” are implied. Thus, for example, implied alternative embodiments to a lens that comprises or includes polycarbonate include embodiments where a lens consists essentially of polycarbonate and embodiments where a lens consists of polycarbonate.

What is claimed is:

1. A display panel comprising:
a meta-reflector; and
an organic light-emitting diode overlying the meta-reflector, the organic light-emitting diode comprising:
an anode disposed adjacent and spaced away from the meta-reflector;
an emissive layer overlying the anode; and
a cathode overlying the emissive layer.

2. The display panel of claim 1, wherein the meta-reflector comprises a nanostructured surface facing the anode.

3. The display panel of claim 1, wherein the organic light-emitting diode is configured to emit polarized light.

4. The display panel of claim 1, wherein the organic light-emitting diode is configured to enhance light emission having a first polarization state and suppress light emission having a second polarization state orthogonal to the first polarization state.

5. The display panel of claim 1, wherein the meta-reflector is electrically connected to the anode.

6. The display panel of claim 1, wherein the cathode comprises a reflector.

7. The display panel of claim 1, further comprising a reflector overlying the cathode.

8. The display panel of claim 1, further comprising a dielectric layer between the meta-reflector and the anode.

9. The display panel of claim 8, wherein the dielectric layer is optically anisotropic.

10. A pixelated display panel comprising:
a plurality of organic light-emitting diodes, each organic light-emitting diode comprising:
an anode,
an emissive layer overlying the anode, and
a common cathode overlying the emissive layer;
a plurality of bottom reflectors, each bottom reflector located proximate to a respective anode; and
a spacer layer located between each of the plurality of bottom reflectors and each of the respective anodes.

11. The pixelated display panel of claim 10, wherein each organic light-emitting diode is configured to emit polarized light.

12. The pixelated display panel of claim 10, wherein each of the plurality of bottom reflectors comprises an independently-configured meta surface.

13. The pixelated display panel of claim 10, wherein the plurality of bottom reflectors comprise a multilayer structure.

14. The pixelated display panel of claim 10, wherein a first bottom reflector comprises a first meta surface facing a corresponding first anode, and a second bottom reflector comprises a second meta surface facing a corresponding second anode.

15. The pixelated display panel of claim 10, wherein the spacer layer has a first thickness between a first bottom reflector and a first anode corresponding to the first bottom reflector, and a second thickness between a second bottom reflector and a second anode corresponding to the second bottom reflector.

16. The pixelated display panel of claim 10, wherein the spacer layer comprises an optically anisotropic dielectric material.

17. The pixelated display panel of claim 10, further comprising a top reflector overlying the common cathode.

18. A display panel comprising:
an organic light-emitting diode disposed between a top reflector and a bottom reflector, wherein the organic light-emitting diode is configured to emit polarized light.

19. The display panel of claim 18, wherein the bottom reflector comprises a nanostructured surface facing the organic light-emitting diode.

20. The display panel of claim 19, wherein the nanostructured surface comprises a plurality of anisotropic elements.
